(19) United States
(12) Patent Application Publication
(10) Pub. No.: US 2012/0236528 A1
(43) Pub. Date: Sep. 20, 2012

(54) MULTILAYER EMI SHIELDING THIN FILM WITH HIGH RF PERMEABILITY

(76) Inventors: John D. Le, Woodbury, MN (US); Robert C. Fitzer, North Oaks, MN (US); Charles L. Bruzzone, Woodbury, MN (US); Stephen P. Maki, North St. Paul, MN (US); Bradley L. Givot, St. Paul, MN (US); David A. Sowatzke, Spring Valley, WI (US)

(21) Appl. No.: 13/512,638

(22) PCT Filed: Nov. 19, 2010
(86) PCT No.: PCT/US10/57372

§ 371 Date: May 30, 2012

Related U.S. Application Data
(60) Provisional application No. 61/265,893, filed on Dec. 2, 2009.

(51) Int. Cl. H05K 9/00; C23C 16/06; C23C 16/56

(52) U.S. Cl. 361/818; 174/391; 427/58; 427/124

(57) ABSTRACT

A flexible multilayer electromagnetic shield is provided that includes a flexible substrate, a thin film layer of a first ferromagnetic material with high magnetic permeability disposed upon the substrate and a multilayer stack disposed upon the first ferromagnetic material. The multilayer stack includes pairs of layers, each pair comprising a polymeric spacing layer and a thin film layer of at least a second ferromagnetic material disposed on the spacing layer. At least one or more of the spacing layers includes an acrylic polymer. Also methods of making the flexible multilayer electromagnetic shield are provided.

### FIELD

Multilayer thin films are provided that have high RF permeability and can be useful for electromagnetic interference shielding and suppression

### BACKGROUND

Miniaturization of electronic devices and high frequency electronic circuits have created a demand for compact and flexible electromagnetic interference/electromagnetic compatible (EMI/EMC) material that also can suppress the degrading effect of electromagnetic interference originating in the devices and circuits or originating in the environment. Additionally EMI/EMC materials can be needed to comply with the electromagnetic compatibility (EMC) specifications for EMI control. EMI control can include EMI shielding, absorption, and/or suppression. Electrically conducting materials can be utilized to primarily provide shielding of electromagnetic radiation.

Lossy magnetic material with high permeability over a certain radiofrequency (RF) range can also be useful to attenuate or suppress the high frequency common mode EMI noise on transmission lines as most noise frequency is usually higher than that of the circuit signal. For EMI suppression, ferrites are widely used. However, they are bulky and may not be suitable for compact devices or in products that have space limitations. Furthermore, the upper limit of frequency suppression in ferrites is on the order of several hundred megahertz (MHz).

### SUMMARY

Thus, there is a need for thin, flexible materials that have high magnetic permeability in the radiofrequency (RF) range. There is a need for materials that can suppress radiofrequency energy over a wider range of frequencies than is currently available in ferrites. Soft magnetic alloys can provide higher permeability at higher frequencies. For example, alloys of NiFe, CoNbZr, FeCoB, nanocrystalline Fe-based oxides and nitrides, and boron-based amorphous alloy are useful in this regard. In today's wireless and compact electronics environment, there is also a need to be able to provide EMI control at high frequencies such as, for example, in the 1-6 gigahertz (GHz) range. And in the electronics industry, as devices are becoming more compact, thinner is better.

In one aspect, a flexible multilayer electromagnetic interference shield is provided that includes a flexible substrate, a thin film layer of a first ferromagnetic material with a high magnetic permeability disposed upon the flexible substrate, and a multilayer stack disposed upon the first ferromagnetic material, the multilayer stack comprises pairs of layers, each pair comprising a spacing layer and a thin film layer of a second ferromagnetic material disposed on the spacing layer. One or more of the spacing layers comprises an acrylic polymer. The spacing layer is preferably a dielectric layer or a non-electrically conductive material to suppress the Eddy current effect. The spacing layer can be made of a ferromagnetic material with relatively lower magnetic permeability.

In another aspect, a method for making a flexible multilayer electromagnetic interference shield is provided that includes providing a substrate, vapor depositing a thin film layer of a first ferromagnetic material upon the substrate, vapor coating and curing an acrylic polymer upon the first ferromagnetic material to form a first polymeric spacing layer, and vapor depositing a thin film of a second ferromagnetic material upon the first spacing layer.

In this application:

“adjacent” refers to layers in the provided filters that are in proximity to other layers. Adjacent layers can be contiguous or can be separated by up to three intervening layers;

“alloy” refers to a composition of two or more metals that have physical properties different than those of any of the metals by themselves;

“contiguous” refers to touching or sharing at least one common boundary;

“dielectric” refers to material that is less conductive than metallic conductors such as silver, and can refer to semiconducting materials, insulators, or metal oxide conductors such as indium-tin-oxide (ITO);

“electromagnetic interference (EMI) shielding” refers to the reflection or absorption of at least one of the components of electromagnetic waves;

The provided flexible multilayer electromagnetic shields can shield or/and suppress radiofrequency energy over a wide range of frequencies. By using thin layers of ferromagnetic material interlayered with spacing materials and by adjusting the numbers of layers, thicknesses of layers, and materials, electromagnetic interference control at high frequencies can be achieved, for example, in the 1-6 gigahertz range. Furthermore, by using vapor-condensed acrylic spacing layers the provided shields can be manufactured in a continuous, roll-to-roll manner.

The above summary is not intended to describe each disclosed embodiment of every implementation of the present invention. The brief description of the drawing and the detailed description which follows more particularly exemplify illustrative embodiments.

### BRIEF DESCRIPTION OF THE DRAWINGS

FIG. 1 is a schematic of an embodiment of a provided electromagnetic shield.

FIG. 2 is a schematic of an embodiment of a provided electromagnetic shield that includes a buffer layer disposed upon the substrate.

FIG. 3 is a schematic of an embodiment of a provided electromagnetic shield that includes a buffer layer and a multilayer stack comprising 4 layers.

### DETAILED DESCRIPTION

In the following description, reference is made to the accompanying set of drawings that form a part of the description hereof and in which are shown by way of illustration several specific embodiments. It is to be understood that other embodiments are contemplated and may be made without departing from the scope or spirit of the present invention. The following detailed description, therefore, is not to be taken in a limiting sense.

Unless otherwise indicated, all numbers expressing feature sizes, amounts, and physical properties used in the specification and claims are to be understood as being modified in all instances by the term “about.” Accordingly, unless indicated to the contrary, the numerical parameters set forth in the foregoing specification and attached claims are approximations that can vary depending upon the desired properties sought to be obtained by those skilled in the art utilizing the teachings disclosed herein. The use of numerical ranges by endpoints includes all numbers within that range (e.g. 1 to 5 includes 1, 1.5, 2, 2.75, 3, 3.80, 4, and 5) and any range within that range.

With the growing trend of miniaturization and portability of multifunctional high speed and high frequency personal electronic devices, such as mobile phone or personal digital assistant (PDA) devices, as well as near field communication (NFC) devices, there is a growing need for the control of electromagnetic interference (EMI) and electromagnetic crosstalk. Meeting this need can be challenging. Radiated EMI noise may need to be controlled in such electronic devices in order to limit its degradative effects, such as, for example, extraneous noise in the radiofrequency (RF) spectrum, and health hazards in the environment. In addition compliance with governmental specification may require control of EMI and electromagnetic crosstalk. Materials are known that can provide EMI shielding and can suppress EMI emissions and thus control electromagnetic interference and noise.

Magnetic materials with high RF permeability can provide EMI shielding or suppression in miniaturized multifunctional electronic devices. Thin conductive magnetic materials can be effective EMI shields for small devices due to their relatively thin skin depth and can be especially effective for near field magnetic shielding. Lossy magnetic materials can be used attenuate or suppress high frequency harmonic noise, common-mode EMI noise on transmission lines, cables, and interconnects, or can be integrated into micro-scale semiconductor circuits. The advantage of using magnetic thin films to suppress EMI noise is related to their high RF impedance, which is proportional to the permeability, frequency, volume/dimension of the magnetic material. Magnetic materials have a complex permeability, μ=μ′−iμ″ that changes with frequency. Materials with a high RF permeability having a high μ″ can be used to obtain high loss of unwanted high frequency noise with a relatively small volume of material. Materials with a high μ′ can be used for near field magnetic shielding for NFC devices which, for example, can improve the reading range for high frequency radio frequency identification tags (HF RFID tag) on metal surfaces as disclosed, for example, in U.S. Pat. No. 7,315,248 (Egbert).

Shielding against EMI is commonly accomplished by reflecting and/or absorbing the incident electromagnetic waves. A large impedance mismatch between the incident medium and the shielding material can lead to relatively high reflectance. As a wave passes through shielding material, its amplitude is attenuated exponentially as a function of skin depth. Due to cost constraints most EMI shielding materials operate simply by reflection. However, many applications can benefit by absorption of the EMI since reflected EMI can also cause additional interference. Non-magnetic metals such as silver, gold, copper, and aluminum, can have high electrical conductivities and can be useful for EMI shielding. However, the metals which are ferromagnetic can be less electrically conductive but can have much higher magnetic permeabilities than other metals. As such, they can be useful for shielding against EMI and particularly for shielding against the magnetic component of EMI. Shielding materials with high magnetic permeability and high electrical conductivity can develop low surface impedance with thinner skin depth that can help to attenuate and to reflect incident waves. In order to absorb EMI it is important to reduce or eliminate eddy currents to allow the incident EMI waves to penetrate the shielding material. Permalloy, which is an alloy of approximately 19 mole % Fe and 81 mole % Ni, and has zero magnetostriction, is a very useful, versatile, and relatively inexpensive material with high magnetic permeability. Permalloy alloy can have from about 18 mole % to about 20 mole % Fe and from about 80 mole% to about 82 mole % Ni. By zero magnetostriction it is meant that the permeability does not change with stress.

Magnetic thin films with high RF permeability can be lossy in a high-frequency range, especially in the gigahertz frequency range, where most of the bulk and the composite ferrite materials have only a small loss generation per thickness, can be advantageous for suppression applications.

Thin ferromagnetic films are known to exhibit the highest possible RF permeability of known magnetic materials. However, with the increase of film thickness, the RF permeability can degenerate because of both effects of eddy currents and out-of-plane magnetization. For these effects to be reduced, films that include multiple layers of thin ferromagnetic layers can be useful. Multilayer constructions of alternating layers of materials with high magnetic permeability and non-magnetic spacing layers have been previously disclosed, for example, in U. S. Pat. No. 5,083,112 (Piotrowski et al.) and U.S. Pat. No. 5,925,455 (Bruzzone et al.) as well as in an article authored by C. A. Grimes, “EMI shielding characteristics of permalloy multilayer thin films”, IEEE Aerospace Applications Conf Proc., IEEE, Computer Society Press Los Alamitos, IEEE, California, USA (1994), pp. 211-221. For example, multilayer, thin film, electronic article surveillance systems which are used for protecting store merchandise and library books can have multiple layers of a magnetic thin film, such as Permalloy, interspaced with a film, such as an inorganic oxide of silicon or aluminum.

A flexible multilayer electromagnetic interference shield is provided that includes a flexible substrate. The substrate is typically a polymer film. Typical substrates can be smooth or textured, uniform or non-uniform and flexible. Polymer films can be suitable for roll-to-roll manufacturing processes. Substrates can also contain other coatings or compounds, for example, abrasion-resistant coatings (hardcoats). Substrates can include flexible plastic materials including thermoplastic films such as polyester (e.g., PET), polyimide, polyolefin, polyacrylate (e.g., poly(methyl methacrylate), PMMA), polycarbonate, polypropylene, high or low density polyethylene, polyethylene naphthalate, polysulfone, polyether sulfone, polyurethane, polyamide, polyvinyl butyral, polyvinyl chloride, polyvinylidenefluoride (PVDF), fluorinated ethylene propylene (FEP), and polyethylene sulfide; and thermoset films such as epoxy, acrylate, cellulose derivatives, polyimide, polyimide benzoxazole, polybenzoxazole, and high T_{g} cyclic olefin polymers. Typically, the substrate can have a thickness of from about 0.01 mm to about 1 mm. Substrates can also be metal foils, flexible printed circuits, printed circuit boards, or any other article on which the multilayer construction can be formulated on or applied to.

Flexible substrates can also be releasable polymer webs such as paper coated with a release liner. Releaseable polymer webs are well known to those of ordinary skill in the art of coatings. Flexible substrates can also include thin polymer coatings on releaseable polymer web. Thin polymer coatings can be epoxy coating, acrylic coating, and can be thermoplastic, thermoset, or photo-curable material. When the substrates are releasable polymer webs, the webs can be separated from the rest of the construction yielding ultra-thin products at application. An adhesive can be used to attach the multilayer construction to an electronic device after it has been removed from a releaseable polymer web.

The provided flexible multilayer electromagnetic interference shield includes a thin film layer of a first ferromagnetic material with a high magnetic permeability disposed upon the flexible substrate. These materials typically include ferromagnetic materials such as Permalloy as discussed above. Other ferromagnetic materials and alloys comprise iron, cobalt, or nickel can be used, including FeN. A multilayer stack is disposed upon the first ferromagnetic material. The multilayer stack includes pairs of layers. Each pair includes a spacing layer and a thin film of at least a second ferromagnetic material disposed upon the spacing layer. One or more of the ferromagnetic material layers may be of the same or different compositions and may have the same or different thicknesses. Each of the thin film layers of ferromagnetic materials have a thickness from about 10 nanometers (nm) to about 1 micrometer (μm), from about 20 nm to about 500 nm, or even from about 30 nm to about 200 nm.

The spacing layers can include at least one acrylic polymer. One or more of the spacing layers can include an acrylic polymer. If more than one spacing layer includes an acrylic polymer, each spacing layer may include an acrylic polymer having the same or different composition. Furthermore, the thicknesses of each of the layers can be the same or different. For example, the layers can include one or more acrylic polymer spacing layers having a thickness of from about 10 nm to about 50 μm, from about 10 nm to about 1 μm, or even from about 50 nm to about 500 nm. In the provided shields, the multilayer stack can include from 2 to about 100, from about 4 to about 50, from about 6 to about 30, from about 6 to about 20, or even from about 6 to about 12 pairs of layers. There may be more than one multilayer stack in the provided shields. If there are multiple multilayer stacks there can be additional spacing layers (one or more) in between each of the multilayer stacks.

The provided flexible multilayer electromagnetic interference shields can also include a buffer layer between the substrate and either the thin film layer of a first ferromagnetic material with a high magnetic permeability or the multilayer stack polymer coating can be utilized for adjust mechanical properties of the multilayer coating. Polymer coatings can also be used as a stress-buffered layer for the multilayer stack to improve adhesion of the stack coating and substrate, to eliminate curling, and to enable multilayer constructions having a large number of bilayers, which, without the buffer coating would be limited to a few bilayer stacks without delaminating and curling. For EMI shield application, polymer coatings can be also used as spacer layers to improve durability and flexural fatigue of the coating, especially for EMI shielding of flexible printed circuit, where flexural endurance is required.

The polymer buffer layer can also be engineered to induce various degrees of crack patterns in the multilayer coating, therefore, minimize surface conductance, which can minimize reflection loss and Eddy current effects where desirable for EMI suppression application. Patterning the multilayer coating can also help to suppress eddy currents for RFID application. Useful buffer layers include thermoset epoxy coatings. The epoxy coatings can be coated on release liner or polymer liner, and kept uncured until multilayer stack deposition. Heat and stress of multilayer stack deposition can induce the epoxy and multilayer stack to crack, which can help to minimize the coating stress, curling and delamination. Other materials for buffer layers can include acrylics and thermoplastic adhesives.

Each pair in the multilayer stack can include a spacing layer. If there is more than one magnetic layer in the multilayer stack then one or more of the spacing layers includes an acrylic polymer. Typically the acrylic polymer can be crosslinked. Crosslinked polymer layers are important during the fabrication of the multilayer stacks. As discussed later, one efficient way of making the multilayer stacks (and the shields, in some cases) is to alternate deposition of the magnetic materials with vapor condensation polymerization of the acrylic spacing layers. It has been unexpectedly found that crosslinked acrylic polymer systems made by vapor condensation polymerization of monomer systems are able to withstand the heat of subsequent vapor deposition of metallic coatings. The processes used to make the provided multilayer shields is discussed later in this specification and is exemplified in the example section.

Useful crosslinked polymeric layers can be formed from a variety of organic materials. Typically, the polymeric layer is crosslinked in situ atop substrate or the previously deposited layer. If desired, the polymeric layer can be applied using conventional coating methods such as roll coating (e.g., gravure roll coating) or spray coating (e.g., electrostatic spray coating), then crosslinked using, for example, UV radiation. Typically, the polymeric layer can be formed by flash evaporation, vapor deposition, and crosslinking of a monomer. Volatilizable acrylamides (such as those disclosed in U. S. Pat. Publ. No. 2008/0160185 (Endle et al.)) and (meth)acrylate monomers are typically used in such a process, with volatilizable acrylate monomers being especially preferred. Fluorinated (meth)acrylates, silicon (meth)acrylates and other volatilizable, free radical-curing monomers can be used. Coating efficiency can be improved by cooling the support. Particularly preferred monomers include multifunctional (meth)acrylates, used alone or in combination with other multifunctional or monofunctional (meth)acrylates, such as phenylthioethyl acrylate, hexanediol diacrylate, ethoxyethyl acrylate, phenoxyethyl acrylate, cyanoethyl(mono)acrylate, isobornyl acrylate, isobornyl methacrylate, octadecyl acrylate, isodecyl acrylate, lauryl acrylate, β-carboxyethyl acrylate, tetrahydrofurfuryl acrylate, dinitrile acrylate, pentafluorophenyl acrylate, nitrophenyl acrylate, 2-phenoxyethyl acrylate, 2-phenoxyethyl methacrylate, 2,2,2-trifluoromethyl(meth)acrylate, diethylene glycol diacrylate, triethylene glycol diacrylate, triethylene glycol dimethacrylate, tripropylene glycol diacrylate, tetraethylene glycol diacrylate, neopentyl glycol diacrylate, propoxylated neopentyl glycol diacrylate, polyethylene glycol diacrylate, tetraethylene glycol diacrylate, bisphenol A epoxy diacrylate, 1,6-hexanediol dimethacrylate, trimethylol propane triacrylate, ethoxylated trimethylol propane triacrylate, propylated trimethylol propane triacrylate, 2-biphenyl acrylate, tris(2-hydroxyethyl)-isocyanurate triacrylate, pentaerythritol triacrylate, phenylthioethyl acrylate, naphthloxyethyl acrylate, EBECRYL 130 cyclic diacrylate (available from Cytec Surface Specialties, West Paterson, N.J.), epoxy acrylate RDX80095 (available from Rad-Cure Corporation, Fairfield, N.J.), CN120E50 and CN120C60(both available from Sartomer, Exton, Pa.), and mixtures thereof. A variety of other curable materials can be included in the crosslinked polymeric layer, e.g., vinyl ethers, vinyl naphthylene, acrylonitrile, and mixtures thereof.

The polymeric spacing layer can be crosslinked in situ after it is applied. In some embodiments, the crosslinked polymeric layer can be formed by flash evaporation, vapor deposition and crosslinking of a monomer as described above. Exemplary monomers for use in such a process include volatilizable (meth)acrylate monomers. In a specific embodiment, volatilizable acrylate monomers are employed. Suitable (meth)acrylates will have a molecular weight that is sufficiently low to allow flash evaporation and sufficiently high to permit condensation on the support. If desired, the polymeric spacing layers can also be applied using conventional coating methods such as roll coating (e.g., gravure roll coating) or spray coating (e.g., electrostatic spray coating), then crosslinked using, for example, UV radiation.

The smoothness and continuity of the multi-layer construction and its adhesion to the substrate or buffer layer can be enhanced by appropriate pretreatment of the support. A typical pretreatment regiment involves electrical discharge pretreatment of the support in the presence of a reactive or non-reactive atmosphere (e.g., plasma, glow discharge, corona discharge, dielectric barrier discharge or atmospheric pressure discharge); chemical pretreatment; flame pretreatment; or application of a nucleating layer such as the oxides and alloys described in C. A. Grimes, “EMI shielding characteristics of permalloy multilayer thin films”, IEEE Aerospace Applications Conf Proc., IEEE, Computer Society Press Los Alamitos, IEEE, California, USA (1994), pp. 211-221. Typical nucleating or undercoat layers for ferromagnetic materials can include Cu, CuAl metal, silicon, silicon nitride and Co₂₁Cr₇₉, as well as other nucleating agents known to those of ordinary skill in the art. These pretreatments can help ensure that the surface of the support will be receptive to the subsequently applied metal layer. Plasma pretreatment is particularly preferred for certain embodiments.

Various functional layers or coatings can be added to the provided electromagnetic shields to alter or to improve their physical or chemical properties. Such layers or coatings can include, for example, low friction coatings (see for example, U.S. Pat. No. 6,744,227 (Bright et al.)), slip particles to make the filter easier to handle during manufacturing; and adhesives such as pressure-sensitive adhesives.

The magnetic or spacing layers can be patterned using a variety of techniques including laser ablation, dry etching, and wet etching. In some embodiments, the provided

EMI shield multilayer stack can be patterned by providing a resist with a pattern. The resist can include hydrocarbon waxes, positive photoresists, negative photoresists or any other resist or masking known to those of ordinary skill in the art of patterning and masking After applying the resist, the multilayer stack can be immersed in an etching tank and exposed to an etching solution to remove the exposed metal or metal alloy layer. Useful etchants include, for example, aqueous HCl, aqueous HNO₃, and aqueous I₂:KI. After etchant exposure, the multilayer stack can be rinsed with water, dried, and used in further operations.

Flexible, multilayer electromagnetic shielding constructions can be designed and fabricated that include a plurality of thin films of high permeability magnetic layers, separated by thin films of dielectric layers. These multilayer constructions can have excellent RF permeability as well as high frequency response. By using a layered design, ferromagnetic resonance frequencies can be tuned to absorb from the megahertz to the gigahertz range. Overall magnetic properties including real and imaginary part of permeability, ferromagnetic resonance, and impedance are a function of parameters such as layer design (thickness of magnetic and polymeric spacing layer), number of layers, process conditions (aligned magnetic field, process temperature, etc.), and the nature of the substrate. Such dynamic relationships between the thickness of the ferromagnetic layers, spacing layers, and number of layers have not been previously established.

In general, thin ferromagnetic films are known to exhibit very high microwave permeability. Among the elements, only cobalt, iron and nickel are strongly ferromagnetic. With the increase of film thickness, the RF permeability degenerates because of both effects of eddy currents and out-of-plane magnetization. For these effects to be reduced, laminates or multilayer of thin ferromagnetic layers are useful. However, since the permeability of multi-layer constructions are additive, with the use of inorganic spacing layer the permeability can degrade noticeably with the number of layers, possibly due to surface quality, internal stress, and limitation of thickness coating of spacing layer. The use of polymeric spacing layers can help to smooth the surface, to lower interlayer stress, and, at thicker spacings, to avoid magnetic coupling between layers.

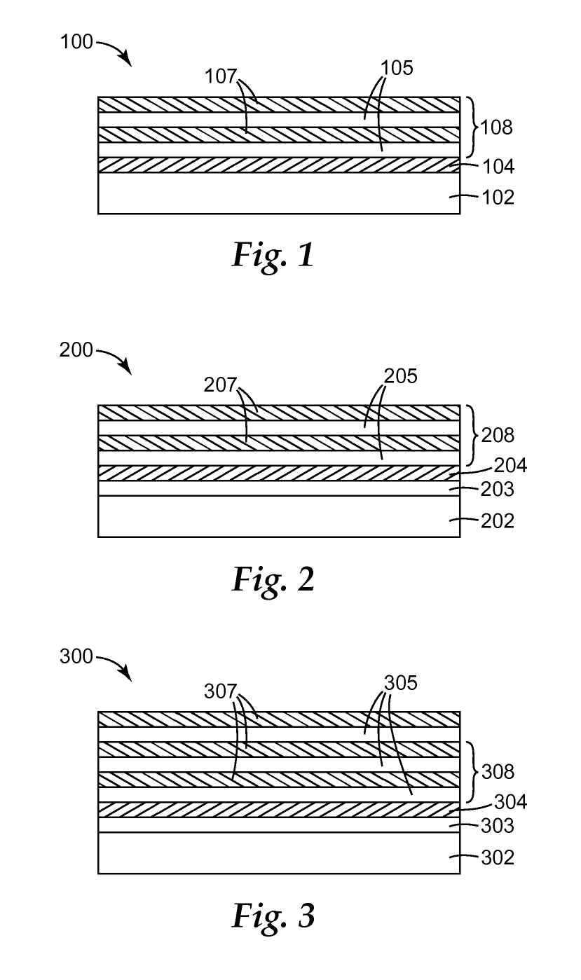

Some embodiments of provided electromagnetic shields are illustrated in the Figures. FIG. 1 is a schematic drawing of one embodiment 100 and includes substrate 102 upon which is disposed first electromagnetic material 104. Multilayer stack 108 that includes two spacer layers 105 and two layers of second ferromagnetic material 107 are disposed upon first ferromagnetic layer 104. At least one of spacing layers 105 includes an acrylic polymer.

FIG. 2 is a schematic illustration of another embodiment of a provided electromagnetic shield. Electromagnetic shield 200 includes substrate 202 upon which is disposed buffer layer 203. Buffer layer 203 can reduce stress in the article when it is flexed which may be needed in order to prevent layers from flaking off. Disposed upon buffer layer 203 is first ferromagnetic layer 204. It is within the scope of this disclosure that, in another embodiment, first ferromagnetic layer 204 may be directly disposed upon the substrate, and buffer layer 203 may be disposed between first ferromagnetic layer 204 and multilayer stack 208. Multilayer stack 208 includes two spacer layers 205 and two layers of second ferromagnetic material 207 are disposed upon first ferromagnetic layer 204.

FIG. 3 is a schematic illustration of yet another embodiment. Electromagnetic shield 300 includes substrate 302 upon which is disposed buffer layer 303. In this embodiment, first electromagnetic layer 304 is disposed upon buffer layer 303 upon which is disposed multilayer stack 308. Multilayer stack 308 includes three spacer layers 305 and three layers of second ferromagnetic material 307.

The provided EMI shields can be used to isolate electronic devices that are sensitive to electromagnetic interference—particularly in application where the magnetic component of the electromagnetic interference needs to be suppressed. For example, EMI shields can be effective for improving reading range RFID systems attached to conductive objects and can help to miniaturize the RFID tag. For shielding of RFID tags on conductive objects such as metals, the signal frequency should be considerably lower than the onset of ferromagnetic resonance. The magnetic shield, which is relatively electrically non-conductive at the tag operating frequency, helps to confine the magnetic field energy and reduce the amount of energy coupled to the conductive substrate which results in higher signal returned to the RFID reader. Use of materials with high magnetic permeability for RFID tags is disclosed, for example, in U. S. Pat. No. 7,315,248 (Egbert).

For broad applications covering noise suppression and magnetic shielding, it may be beneficial to be able to control the RF permeability and the ferromagnetic resonance (FMR) frequency by material design and process. Reducing RF conductance of magnetic thin films to reduce reflection loss for EMI suppressor can be beneficial as taught, for example, by S. Yoshida et al, “High frequency Noise Suppression in Downsized Circuits using Magnetic Granular Films”, IEEE Transactions on Magnetics, 37(4), 2401 (July 2001). Additionally, electromagnetic shields can be used for Eddy current suppression in RFID applications.

Objects and advantages of this invention are further illustrated by the following examples, but the particular materials and amounts thereof recited in these examples, as well as other conditions and details, should not be construed to unduly limit this invention.

### EXAMPLES

### Materials

TABLE 1
Materials

| Identification | Description |
|---|---|
| IRR214 | A proprietary hydrocarbon diacrylate, |
| | available under the trade designation |
| | “IRR214” from UCB Chemicals, Drogenbos, Belgium. |
| CN147 | An acidic acrylate oligomer available |
| | under the trade designation “CN147” |
| | from Sartomer Company, Inc., Exton, Pennsylvania. |
| SR335 | Lauryl acrylate, available under the trade designation |
| | “SR335” from Sartomer Company, Inc. |
| 1173 | A photo initiator, available under the trade |
| | designation “Ciba ® Darocur ® 1173” from |
| | Ciba Specialty Chemicals, Basel, Switzerland. |
| Formulation 1 | An acrylate monomer solution |
| | having 67 parts (by wt.) IRR214, 6 parts |
| | CN147, 23 parts SR335 and 4 parts 1173. |

### Test Methods

### Layer Thickness Measurements

Layer thicknesses were determined from film cross sections using an electron microscope, a Tabletop Microscope TM-1000 available from Hitachi High Technologies Americas, Schaumburg, Ill. Film cross-sections were exposed for microscopic observation by cutting the film with a scissor. Images were collected with the microscope operating typically at an accelerating voltage of 15 kV, magnification of 10 k, working distance of 5660 μm, and emission current of 61800 nA.

### Magnetic Permeability Measurement

The permeability of the film samples was measured with Agilent 4291A Impedance Analyzer utilizing Agilent 16454A 20 mm test fixture available from Agilent Technologies, Santa Clara, Calif. The 16454A is designed for accurate permeability measurements of toroidal-shaped magnetic materials and complex permeability is calculated from the inductance with and without the toroid. Film samples were die-cut to toroidal-shaped dimension of 19.2 mm outer diameter and 5.65 mm inner diameter. Tested material was a single ply of die-cut part or a stack of up to 5 die-cut parts for better signal-to-noise measurements. The tests were done with presumed magnetic material thickness of 10 micrometer and the calculated complex permeability was then normalized by use of the magnetic material layer thickness, as determined from the electron microscope.

### Example 1

A polyimide web with a thickness of 0.051 mm (2 mil) and a width of 35.6 cm (14 inch) available as Kapton polyimide film 220H (D11261256) from E.I. du Pont de Nemours and Company, Wilmington, Del., was loaded into a roll to roll vacuum chamber. The chamber contains a coating drum capable of being heated, an infrared heater and three coating sources positioned sequentially within the chamber. Two of the coating sources were inductively heated sublimation sources, one each on the left and right hand side of the drum, and the other was a NiFe source located under the drum. The NiFe source consists of two graphite crucibles located cross web which are heated with an electron beam system available under the trade designation TEMESCAL from Edwards, Ltd., Crawley, West Sussex, United Kingdom. The NiFe wire was fed into the crucibles where the e-beam melted and evaporated it onto the web as the web moved over the coating drum. Prior to coating, the polyimide was degassed by running the web through the chamber under vacuum and contacting the web to the coating drum set at 300° C. while also applying infrared heating. The location of the IR heater for degassing is in the upper portion of the web path in the main chamber prior to the drum. The web speed used for degassing was 4.9 m/min (16 fpm) at a vacuum in the range of 10⁻⁵ torr. After degas, the web was rewound back into the right hand side chamber so that it was ready for the first coating of a NiFe layer.

The first layer of NiFe was deposited in 4 passes at a web speed of 25.9 m/min (85 feet/min) at a vacuum of about 2×10⁻⁵ ton. The coating drum was set at a temperature of 300° C. The NiFe wire was about 81.5 wt. % Ni and 18.5 wt. % Fe having a 2 mm (0.080 inch) diameter available from Metalwerks, PMD, Aliquippa, Pa. The NiFe wire was fed at a rate of 55.9 cm/min (22 inch/min) with a range e-beam power of 420-640 mA, typically about 500 mA. A range of e-beam power was used to accommodate the NiFe wire feed rate. Additional coating passes were done by reversing and/or forwarding the web accordingly. After NiFe deposition, the NiFe coated polyimide web was removed from the apparatus and loaded into a second roll to roll vacuum chamber for coating and curing of the polymer layer.

The pressure in the second vacuum chamber was reduced to about 3×10⁻⁵ torr (0.004 Pa). Nitrogen gas was introduced into the vacuum chamber and regulated to 0.300 torr (40 Pa). The NiFe coated polyimide web was sequentially plasma treated at 600 watts and a frequency of 400 kHz, acrylate coated and cured during one pass through the vacuum chamber at a web speed of about 7.9 m/min (25.9 ft/min). Formulation 1 was the acrylate monomer solution used to produce the acrylate coating. Prior to coating, about 20 ml of Formulation 1 was degassed in a vacuum bell jar at 0.010 torr for about 20 minutes. The monomer solution was loaded into a syringe. A syringe pump was used to pump the solution through an ultrasonic atomizer. The flow rate was 0.3 mL/min. After atomization, the solution was flash evaporated at a temperature of about 275° C., followed by condensing of the solution vapor onto the NiFe surface of the NiFe coated polyimide web. Condensation was facilitated by contacting the opposite surface of the polyimide web to the circumference of a drum maintained at a temperature of −15° C. The condensed solution was cured using low-pressure-mercury-arc (germicidal) UV bulbs. After curing of the acrylate, the polyimide web was removed from the chamber and remounted in the first roll to roll vacuum chamber, previously described.

A second NiFe layer was deposited adjacent to the polymer layer using substantially the same process conditions as those used to deposit the first NiFe layer, producing Example 1. The layer thicknesses and magnetic permeability of the film was measured following the above test methods. Tabulated values of the various layer thicknesses and the real and imaginary part of the magnetic permeability at a frequency of 0.12 GHz and 0.5 GHz are shown in Table 3.

### Examples 2 through 6

Examples 2 though 6 were prepared in a similar manner as that of Example 1, except the process conditions were adjusted to modify the NiFe layer thicknesses and the polymer layer thickness, respectively. The NiFe layer thicknesses were adjusted by increasing the number of passes for NiFe deposition. For each example, the number of passes used to deposit the NiFe layer was equivalent for the first and second NiFe layers. The polymer layer thickness was adjusted by modifying the coating line speed and the syringe pump flow rate during the deposition of the acrylate monomer solution, formulation 1. Table 2 summarized these process changes. The layer thicknesses and magnetic permeability of the films was measured following the above test methods. Tabulated values of the various layer thicknesses and the real and imaginary part of the magnetic permeability at a frequency of 0.12 GHz and 0.5 GHz are shown in Table 3.

TABLE 2
NiFe and Acrylate Monomer Coating Process Conditions

| | # NiFe | Acrylate | Acryalte |
|---|---|---|---|
| | Coating | Monomer Coating | Monomer Flow |
| Example | Passes | Line Speed (m/min) | Rate (mL/min) |
| 1 | 4 | 7.9 | 0.3 |
| 2 | 10 | 7.9 | 0.3 |
| 3 | 20 | 7.9 | 0.3 |
| 4 | 4 | 2.6 | 1.0 |
| 5 | 10 | 2.6 | 1.0 |
| 6 | 20 | 2.6 | 1.0 |

TABLE 3
Layer Thicknesses and Magnetic Permeability

| | Layer Thickness (nm) | | | Magnetic Permeability | | | |
|---|---|---|---|---|---|---|---|
| | NiFe | Acrylate | NiFe | Real @ | Imaginary @ | Real @ | Imaginary @ |
| Example | (1st layer) | Coating | (2nd layer) | 0.12 GHz | 0.12 GHz | 0.5 GHz | 0.5 GHz |
| 1 | 159 | 159 | 191 | 304.2 | 5.2 | 407.7 | 108.8 |
| 2 | 542 | 223 | 574 | 58.0 | 0.4 | 95.2 | 28.1 |
| 3 | 1150 | 191 | 1050 | 69.8 | 4.2 | 66.3 | 40.9 |
| 4 | 96 | 1120 | 128 | 211.2 | 23.9 | 260.8 | 135.7 |
| 5 | 319 | 861 | 414 | 85.2 | −4.4 | 136.3 | 52.3 |
| 6 | 1120 | 765 | 1430 | 60.5 | −6.9 | 62.9 | 31.7 |

Various modifications and alterations to this invention will become apparent to those skilled in the art without departing from the scope and spirit of this invention. It should be understood that this invention is not intended to be unduly limited by the illustrative embodiments and examples set forth herein and that such examples and embodiments are presented by way of example only with the scope of the invention intended to be limited only by the claims set forth herein as follows. All references cited in this disclosure are herein incorporated by reference in their entirety.

1. A flexible multilayer electromagnetic interference shield comprising:
a flexible substrate;
a thin film layer of a first ferromagnetic material with a high magnetic permeability disposed upon the flexible substrate; and
a multilayer stack disposed upon the first ferromagnetic material, the multilayer stack comprises pairs of layers, each pair comprising:
a spacing layer; and
a thin film layer of at least a second ferromagnetic material disposed on the spacing layer,
wherein one or more of the spacing layers comprises an acrylic polymer.

2. A flexible multilayer electromagnetic interference shield according to claim 1, wherein the substrate comprises a polymeric film.

3. A flexible multilayer electromagnetic interference shield according to claim 2, wherein the polymeric film is selected from polyesters, polyimides, polyolefins, or combinations thereof

4. A flexible multilayer electromagnetic interference shield according to claim 1, wherein the substrate comprises a release liner.

5. A flexible multilayer electromagnetic interference shield according to claim 1, wherein the first ferromagnetic material and the second ferromagnetic material comprise iron.

6. A flexible multilayer electromagnetic interference shield according to claim 5, wherein the first ferromagnetic material, the second ferromagnetic material, or both further comprise at least one other metal selected from nickel, copper, molybdenum, manganese, silicon, and combinations thereof

7. A flexible multilayer electromagnetic interference shield according to claim 6, wherein the ferromagnetic materials comprise from about 80 weight percent to about 82 weight percent nickel and from about 18 weight percent to about 20 weight percent iron.

8. A flexible multilayer electromagnetic interference shield according to claim 5, wherein each of the thin film layers of ferromagnetic materials have a thickness of from about 10 nm to about 1 micrometer

9. A flexible multilayer electromagnetic interference shield according to claim 1, wherein the one or more acrylic polymer spacing layers has a thickness from about 10 nm to about 50 micrometer.

10. A flexible multilayer electromagnetic interference shield according to claim 1, wherein the multilayer stack comprises 2 to 100 pairs of layers.

11. A flexible multilayer electromagnetic interference shield according to claim 1 further comprising a polymeric buffer layer disposed between the substrate and the thin film layer of a first ferromagnetic material.

12. A flexible multilayer electromagnetic interference shield according to claim 1, further comprising a spacing layer disposed between the substrate and the first ferromagnetic layer.

13. A flexible multilayer electromagnetic interference shield according to claim 1, further comprising a buffer layer.

14. A flexible multilayer electromagnetic interference shield according to claim 13, wherein the buffer layer is disposed between the substrate and the first ferromagnetic layer, between the first ferromagnetic layer and the multilayer stack, or a combination thereof

15. An electronic display comprising a flexible multilayer electromagnetic interference shield according to claim 1.

16. A method for making a flexible multilayer electromagnetic interference shield comprising:
providing a substrate;
vapor depositing a thin film layer of a first ferromagnetic material upon the substrate;
vapor coating and curing an acrylic polymer upon the first ferromagnetic material to form a first polymeric spacing layer; and
vapor depositing a thin film of a second ferromagnetic material upon the first spacing layer.

17. A method for making a flexible multilayer electromagnetic interference shield according to claim 16 further comprising:
repeating the vapor coating and curing of an acrylic polymer and the vapor coating and curing of an acrylic polymer at least one additional time.

18. A method for making a flexible multilayer electromagnetic interference shield, according to claim 16, wherein the first and the second ferromagnetic materials comprise iron.

19. A method for making a flexible multilayer electromagnetic interference shield according to claim 17, wherein the first ferromagnetic material, the second ferromagnetic material, or both further comprise at least one other metal selected from nickel, copper, molybdenum, manganese, silicon, and combinations thereof.

20. A method for making a flexible multilayer electromagnetic interference shield according to claim 17, wherein the ferromagnetic materials comprise from about 80 weight percent to about 82 weight percent nickel and from about 18 weight percent to about 20 weight percent iron.

21. A method for making a flexible multilayer electromagnetic interference shield according to claim 16, wherein each of the thin film layers of ferromagnetic materials have a thickness of from about 10 nm to about 1 μm.

22. A method for making a flexible multilayer electromagnetic interference shield according to claim 16, wherein each of the polymeric spacing layers has a thickness of from about 10 nm to about 50 μm.
